(19) United States
(12) Patent Application Publication
(10) Pub. No.: US 2017/0158491 A1
(43) Pub. Date: Jun. 8, 2017

(54) LASER RESEAL HAVING SPECIAL DIAPHRAGM STRUCTURE

(71) Applicant: Robert Bosch GmbH, Stuttgart (DE)

(72) Inventors: Alexander Ilin, Ludwigsburg (DE); Mawuli Ametowobla, Stuttgart (DE); Philip Kappe, Hildesheim (DE)

(21) Appl. No.: 15/364,675

(22) Filed: Nov. 30, 2016

(30) Foreign Application Priority Data
Dec. 8, 2015 (DE) 102015224520.9

(51) Int. Cl. B81B 7/00; B81C 1/00

(52) U.S. Cl. CPC B81B 7/0038; B81C 1/00285; B81B 2201/0235; B81B 2201/0242; B81B 2203/0127; B81C 2203/0172; B81C 2203/0109

(57) ABSTRACT

A method is described for manufacturing a micromechanical component including a substrate and including a cap, which is connected to the substrate and, together with the substrate, encloses a first cavity, a first pressure prevailing and a first gas mixture having a first chemical composition being enclosed in the first cavity. An access opening connecting the first cavity to surroundings of the micromechanical component is formed in the substrate or in the cap. The first pressure and/or the first chemical composition is adjusted in the first cavity. The access opening is sealed by introducing energy or heat into an absorbing part of the substrate or of the cap with the aid of a laser, the access opening being essentially completely filled by a material area of the substrate or the cap, which enters a liquid aggregate state, between a first plane and a second plane.

### CROSS REFERENCE

The present application claims the benefit under 35 U.S.C. §119 of German Patent Application No. DE 102015224520.9 filed on Dec. 8, 2015, which is expressly incorporated herein by reference in its entirety.

### BACKGROUND INFORMATION

A method is described in PCT Application No. WO 2015/120939 A1 in which, when a certain internal pressure is desired in a cavity of a micromechanical component or a gas mixture having a certain chemical composition is to be enclosed in the cavity, the internal pressure or the chemical composition is frequently adjusted during capping of the micromechanical component or during the bonding process between a substrate wafer and a cap wafer. During capping, for example, a cap is connected to a substrate, whereby the cap and the substrate together enclose the cavity. By adjusting the atmosphere or the pressure and/or the chemical composition of the gas mixture present in the surroundings during capping, it is thus possible to adjust the particular internal pressure and/or the particular chemical composition in the cavity.

With the aid of the method described in PCT Application No. WO 2015/120939 A1, an internal pressure may be adjusted in a targeted way in a cavity of a micromechanical component. It is in particular possible with the aid of this method to manufacture a micromechanical component having a first cavity, a first pressure and a first chemical composition being adjustable in the first cavity, which differ from a second pressure and a second chemical composition at the time of capping.

In the method for targeted adjusting of an internal pressure in a cavity of a micromechanical component according to PCT Application No. WO 2015/120939 A1, a narrow access channel to the cavity is created in the cap or in the cap wafer, or in the substrate or in the sensor wafer. Subsequently, the cavity is flooded with the desired gas and the desired internal pressure via the access channel. Finally, the area around the access channel is locally heated with the aid of a laser, the substrate material liquefies locally and hermetically seals the access channel during solidification.

### SUMMARY

It is an object of the present invention to provide a method for manufacturing a micromechanical component which is mechanically robust and has a long service life compared to the related art, in a simple and cost-effective manner compared to the related art. It is a further object of the present invention to provide a micromechanical component which is compact, mechanically robust and has a long service life compared to the related art.

According to the present invention, this applies, in particular, to a micromechanical component having one (first) cavity. With the aid of the method according to the present invention and the micromechanical component according to the present invention, it is furthermore also possible to implement a micromechanical component in which a first pressure and a first chemical composition may be adjusted in the first cavity, and a second pressure and a second chemical composition may be adjusted in a second cavity. For example, such a method for manufacturing micromechanical components is provided, for which it is advantageous if a first pressure is enclosed in a first cavity and a second pressure is enclosed in a second cavity, the first pressure being different from the second pressure. This is the case, for example, when a first sensor unit for rotation rate measurement and a second sensor unit for acceleration measurement are to be integrated into a micromechanical component.

The object may be achieved in accordance with example embodiments of the present invention by providing that the access opening is essentially completely filled by a material area of the substrate or the cap, which enters a liquid aggregate state in the third method step, between a first plane, which extends essentially in parallel to a main extension plane of the substrate and is formed on a side, which faces away from the first cavity, of an area of the access opening formed essentially perpendicularly to the main extension plane, and a second plane, which extends essentially in parallel to the main extension plane of the substrate and is situated on a side, which faces toward the first cavity, of the area of the access opening formed essentially perpendicularly to the main extension plane.

In this way, a method for manufacturing a micromechanical component is provided in a simple and cost-effective manner, using which the access opening is fillable essentially completely. Because the access opening is sealed essentially along its complete length, notch effects, which may occur if an access opening is only partially sealed, may be reduced or avoided. In particular, notch effects, which may occur at a transition between a non-sealed area of the access opening and the sealed area of the access opening, may be reduced or avoided using the method according to the present invention. By reducing or avoiding such notch effects, a micromechanical component which is mechanically robust compared to the related art and has a long service life is provided in a way which is simple and cost-effective compared to the related art.

Furthermore, it is less problematic using the method according to the present invention if the substrate material is only locally heated and the heated material expands or contracts in relation to its surroundings both during solidification and also during cooling, because the intrinsic mechanical stress produced by the expansion or contraction during solidification and during cooling may not result in cracking as a result of the notch effects. It is also less problematic that tensile stresses may arise in the seal area, because these tensile stresses may not result in cracking as a result of the notch effects. It is therefore possible using the method according to the present invention to increase a critical maximum intrinsic stress in comparison to the related art. Spontaneous cracking which occurs depending on the stress and material and also cracking in the event of thermal or mechanical stress of the micromechanical component is thus also less probable during the further processing or in the field.

The term “micromechanical component” is understood in the context of the present invention to mean that the term includes both micromechanical components as well as microelectromechanical components.

The present invention is preferably provided for a micromechanical component having a cavity or its manufacture. However, the present invention is also provided, for example, for a micromechanical component having two cavities or having more than two, i.e., three, four, five, six or more than six, cavities.

The access opening is preferably sealed with the aid of a laser by introducing energy or heat into a part of the substrate or of the cap that absorbs this energy or this heat. In this case, energy or heat is preferably introduced chronologically in succession into the respective absorbing part of the substrate or of the cap of multiple micromechanical components, which are manufactured together, for example, on one wafer. Alternatively, however, a chronologically parallel introduction of the energy or heat into the respective absorbing part of the substrate or of the cap of multiple micromechanical components is also provided, for example, using multiple laser beams or laser devices.

Advantageous embodiments and refinements of the present invention are described herein with reference to the drawings.

According to one preferred refinement, it is provided that the cap, together with the substrate, encloses a second cavity, a second pressure prevailing and a second gas mixture having a second chemical composition being enclosed in the second cavity.

According to one preferred refinement, it is provided that the energy or heat is introduced into the absorbing part of the substrate or the cap in such a way that the first plane extends essentially along a surface, which faces away from the first cavity, of the substrate or the cap. This advantageously enables the access opening to be filled with the material area completely up to the surface facing away from the first cavity.

According to one preferred refinement, it is provided that the energy or heat is introduced into the absorbing part of the substrate or the cap in such a way that the second plane extends essentially along a surface, which faces toward the first cavity, of the substrate or the cap. This advantageously enables the access opening to be filled with the material area completely up to the surface facing toward the first cavity.

According to one preferred refinement, it is provided that the energy or heat is introduced into the absorbing part of the substrate or the cap in such a way that the material area has an extension from the first plane up to the second plane before the third method step. This advantageously enables the substrate or the cap to be melted over essentially the entire thickness of the substrate or the cap.

A further subject matter of the present invention is a micromechanical component having a substrate and a cap connected to the substrate and, together with the substrate, enclosing a first cavity, a first pressure prevailing and a first gas mixture having a first chemical composition being enclosed in the first cavity, the substrate or the cap including a sealed access opening, the access opening being essentially completely filled by a material area of the substrate or the cap, which enters a liquid aggregate state during the sealing of the access opening, between a first plane, which extends essentially in parallel to a main extension plane of the substrate and is formed on a side, which faces away from the first cavity, of an area of the access opening formed essentially perpendicularly to the main extension plane, and a second plane, which extends essentially in parallel to the main extension plane of the substrate and is situated on a side, which faces toward the first cavity, of the area of the access opening formed essentially perpendicularly to the main extension plane. This advantageously provides a compact, mechanically robust and cost-effective micromechanical component having an adjusted first pressure. The aforementioned advantages of the method according to the present invention also apply correspondingly to the micromechanical component according to the present invention.

According to one preferred refinement, it is provided that the substrate or the cap includes silicon. This advantageously enables the micromechanical component to be manufactured using standard methods of semiconductor layer technology.

According to one preferred refinement, it is provided that the first plane extends essentially along a surface, which faces away from the first cavity, of the substrate or the cap.

According to one preferred refinement, it is provided that the second plane extends essentially along a surface, which faces toward the first cavity, of the substrate or cap.

According to one preferred refinement, it is provided that the material area has an extension from the first plane up to the second plane before the sealing of the access opening.

According to one preferred refinement, it is provided that the cap, together with the substrate, encloses a second cavity, a second pressure prevailing and a second gas mixture having a second chemical composition being enclosed in the second cavity. In this way, a compact, mechanically robust and cost-effective micromechanical component having an adjusted first pressure and second pressure is advantageously provided.

According to one preferred refinement, it is provided that the first pressure is lower than the second pressure, a first sensor unit for rotation rate measurement being situated in the first cavity, and a second sensor unit for acceleration measurement being situated in the second cavity. In this way, a mechanically robust micromechanical component for rotation rate measurement and acceleration measurement, having optimal operating conditions for both the first sensor unit and the second sensor unit, is advantageously provided.

### BRIEF DESCRIPTION OF THE DRAWINGS

FIG. 1 shows a micromechanical component having an open access opening according to one exemplary specific embodiment of the present invention in a schematic representation.

FIG. 2 shows the micromechanical component according to FIG. 1 having a sealed access opening in a schematic representation.

FIG. 3 shows a method for manufacturing a micromechanical component according to one exemplary specific embodiment of the present invention in a schematic representation.

FIG. 4 shows a micromechanical component having an open access opening according to a further exemplary specific embodiment of the present invention in a schematic representation.

FIG. 5 and FIG. 6 show the micromechanical component according to FIG. 4 having a sealed access opening in schematic representations.

### DETAILED DESCRIPTION OF EXAMPLE EMBODIMENTS

Identical parts are denoted by the same reference numerals in the various figures and are therefore generally also cited or mentioned only once.

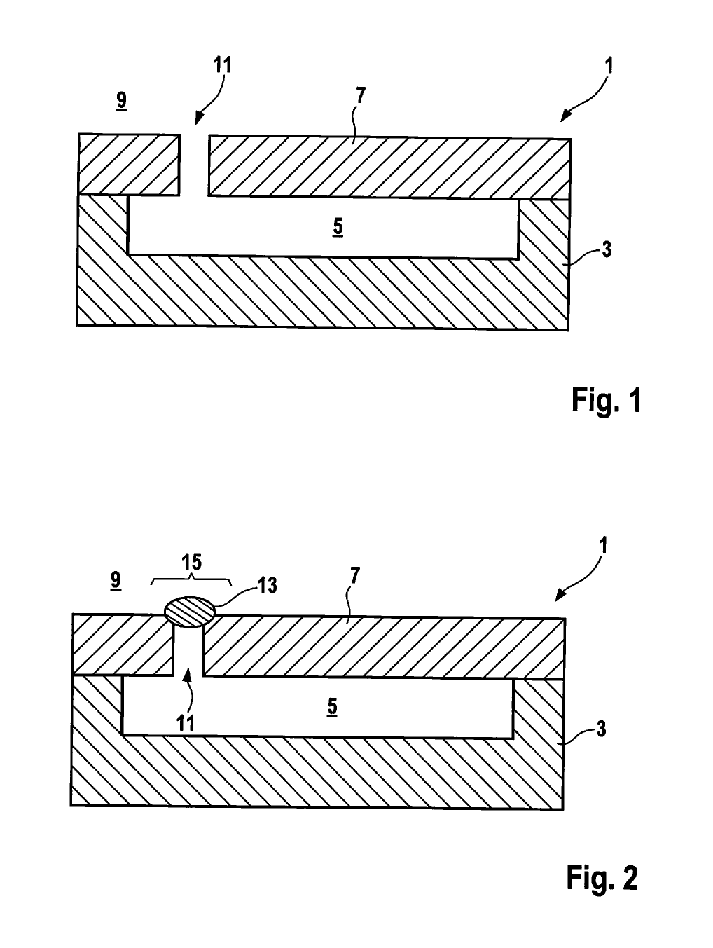

FIG. 1 and FIG. 2 show schematic representations of a micromechanical component 1 having an open access opening 11 in FIG. 1, and having a sealed access opening 11 in FIG. 2, according to one exemplary specific embodiment of the present invention. Micromechanical component 1 includes a substrate 3 and a cap 7. Substrate 3 and cap 7 are, preferably hermetically, connected to one another and together enclose a first cavity 5. For example, micromechanical component 1 is designed in such a way that substrate 3 and cap 7 additionally together enclose a second cavity. The second cavity, however, is not shown in FIG. 1 and in FIG. 2.

For example, a first pressure prevails in first cavity 5, in particular when access opening 11 is sealed, as shown in FIG. 2. Moreover, a first gas mixture having a first chemical composition is enclosed in first cavity 5. In addition, for example, a second pressure prevails in the second cavity, and a second gas mixture having a second chemical composition is enclosed in the second cavity. Access opening 11 is preferably situated in substrate 3 or in cap 7. In the present exemplary embodiment, access opening 11 is situated in cap 7 by way of example. According to the present invention, however, it may also be alternatively provided that access opening 11 is situated in substrate 3.

It is provided, for example, that the first pressure in first cavity 5 is lower than the second pressure in the second cavity.

It is also provided, for example, that a first micromechanical sensor unit for rotation rate measurement, which is not shown in FIG. 1 and FIG. 2, is situated in first cavity 5, and a second micromechanical sensor unit for acceleration measurement, which is not shown in FIG. 1 and FIG. 2, is situated in the second cavity.

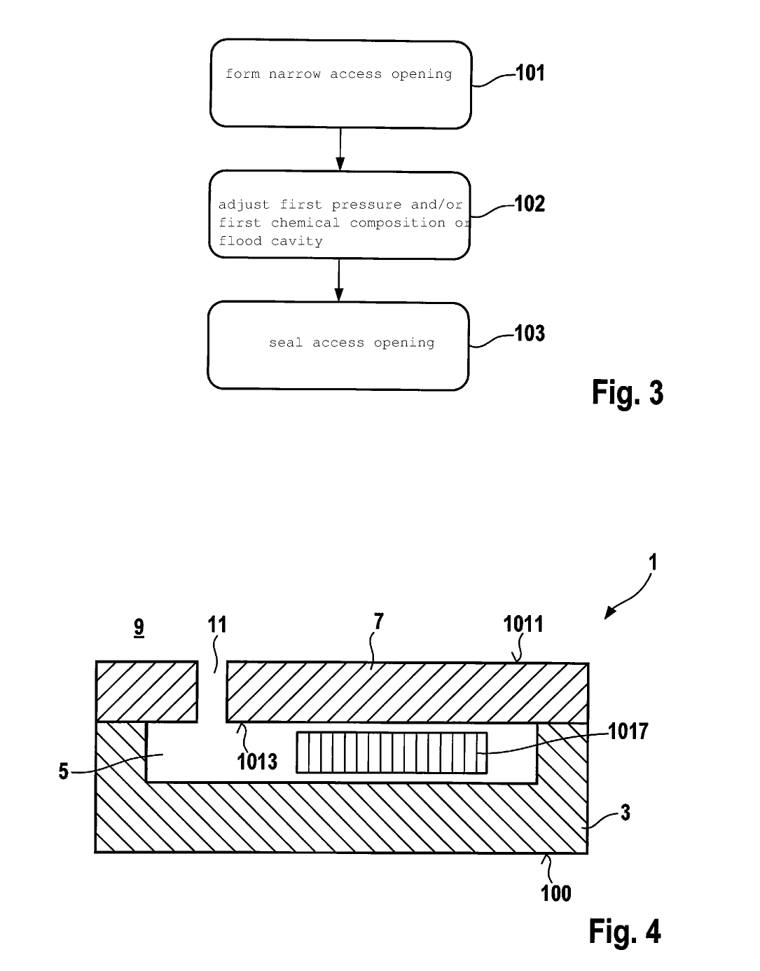

FIG. 3 shows a method for manufacturing micromechanical component 1 according to one exemplary specific embodiment of the present invention in a schematic representation. In this method,
in a first method step 101, in particular narrow access opening 11 connecting first cavity 5 to surroundings 9 of micromechanical component 1 is formed in substrate 3 or in cap 7. FIG. 1 shows micromechanical component 1 after first method step 101 by way of example. Moreover,
in a second method step 102, the first pressure and/or the first chemical composition in first cavity 5 is adjusted, or first cavity 5 is flooded with the desired gas and the desired internal pressure via the access channel. Furthermore, for example,
in a third method step 103, access opening 11 is sealed by introducing energy or heat with the aid of a laser into an absorbing part of substrate 3 or cap 7. Alternatively, for example, it is also provided that
in the third method step 103, the area around the access channel is preferably heated only locally by a laser, and the access channel is hermetically sealed. It is thus advantageously possible to also provide the method according to the present invention with energy sources other than with a laser for sealing access opening 11. FIG. 2 shows micromechanical component 1 after third method step 103 by way of example.

It is provided, for example, that in a fourth method step, substrate 3 is connected to cap 7, the fourth method step being carried out before or after first method step 101.

Chronologically after third method step 103, it is possible for mechanical stresses to occur in a lateral area 15, shown by way of example in FIG. 2, on a surface, which faces away from cavity 5, of cap 7 and in the depth perpendicularly to a projection of lateral area 15 onto the surface, i.e., along access opening 11 and in the direction of first cavity 5 of micromechanical component 1. These mechanical stresses, in particular local mechanical stresses, prevail in particular on and in the vicinity of an interface between a material area 13 of cap 7, which in third method step 103 transitions into a liquid aggregate state and after third method step 103 transitions into a solid aggregate state and seals access opening 11, and a remaining area of cap 7, which remains in a solid aggregate state during third method step 103. In FIG. 2, material area 13 of cap 7 sealing access opening 11 is to be regarded only schematically or is shown only schematically, in particular with respect to its lateral extension or form, extending in particular in parallel to the surface, and in particular with respect to its expansion or configuration perpendicularly to the lateral extension, running in particular perpendicularly to the surface.

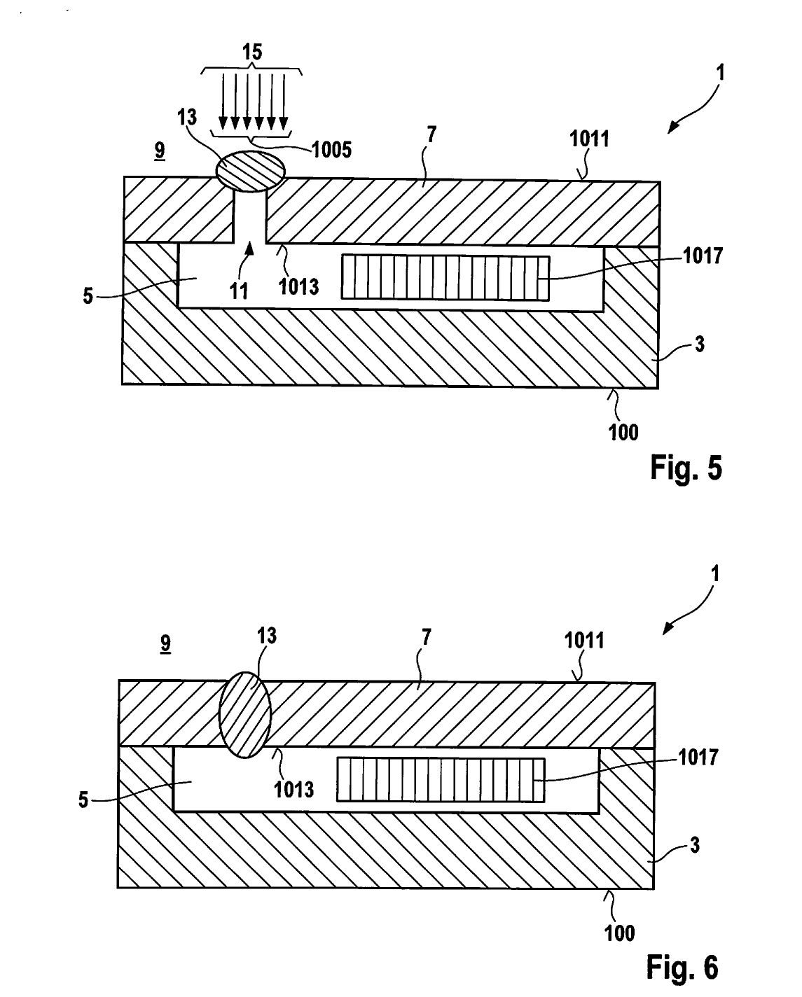

FIG. 4 and FIG. 5 show a schematic representation of a micromechanical component 1 having an open access opening 11 in FIG. 4 and having a sealed access opening 11 in FIG. 5 according to another exemplary specific embodiment of the present invention. It is shown by way of example in this case that a first micromechanical sensor unit for rotation rate measurement 1017 or a MEMS element is situated in first cavity 5. FIG. 4 and FIG. 5 also show a main extension plane 100 of substrate 3 by way of example. In addition, FIG. 5 shows, by way of example, a surface 1011, which extends essentially in parallel to main extension plane 100, on a side of cap 7 facing away from first cavity 5, and a laser beam 1005. Furthermore, FIG. 5 shows a surface 1013, which extends essentially in parallel to main extension plane 100 and faces toward first cavity 5, of cap 7.

FIG. 6 shows by way of example that access opening 11 is essentially completely filled by material area 13, which enters a liquid aggregate state during the sealing of access opening 11, of substrate 3 or cap 7 between a first plane, which extends essentially in parallel to main extension plane 100 of substrate 3 and is situated on a side, which faces away from first cavity 5, of an area of access opening 11 formed essentially perpendicularly to main extension plane 100, and a second plane, which extends essentially in parallel to main extension plane 100 of substrate 3 and is situated on a side, which faces toward first cavity 5, of the area of access opening 11 formed essentially perpendicularly to main extension plane 100.

It is provided in this case, for example, that the first plane extends essentially along a surface 1011, which faces away from first cavity 5, of substrate 3 or cap 7. Alternatively or additionally, it is also provided, for example, that the second plane extends essentially along a surface 1013, which faces toward first cavity 5, of substrate 3 or cap 7.

For example, it is also provided that material area 13 has an extension from the first plane up to the second plane before the sealing of access opening 11. In other words, the completely filled access opening shown by way of example in FIG. 6 is achieved, for example, in that the thickness of substrate 3 or cap 7 or of the diaphragm to be sealed is adapted to the third method step or to the melting process in such a way that in the third method step or during the laser sealing, substrate 3 or cap 7 or the diaphragm is melted over the entire thickness of the substrate or cap 7 or the diaphragm and therefore access channel 11 is sealed on its complete length at its or the access opening 11. One advantage of this configuration is, for example, dispensing with the transition, which occurs if the channel or access opening 11 is only partially sealed, of unsealed and sealed channel or access opening 11, which may result in a notching effect and therefore additional weakening of the mechanical stability. Due to the complete melting of substrate 3 or cap 7 or the diaphragm, for example, the notch is dispensed with and an approximately homogeneous two-dimensional stress state results, for example, around the sealed channel or around sealed access opening 11, which also has a favorable effect on the stability of the seal of access opening 11.

Finally, it is provided, for example, that the length of access channel 11 or access opening 11 essentially perpendicularly in relation to main extension plane 100, for example, corresponding to the local thickness of the cap wafer, and the melting depth by way of the laser process or the extension of material area 13 essentially perpendicularly in relation to main extension plane 100 are adapted to one another in such a way that the channel or access opening 11 is melted and thus sealed along its entire length

In addition, it is provided, for example, that the introduction of the energy or heat takes place by adjusting the extension of the absorbing part and by adjusting the strength of the absorption in the absorbing part in such a way that the channel or access opening 11 is melted and thus sealed along its entire length.

What is claimed is:

1. A method for manufacturing a micromechanical component including a substrate and including a cap, which is connected to the substrate, the cap, together with the substrate, enclosing a first cavity, a first pressure prevailing and a first gas mixture having a first chemical composition being enclosed in the first cavity, the method comprising:
in a first method step, forming in the substrate or cap an access opening connecting the first cavity to surroundings of the micromechanical component;
in a second method step, adjusting in the first cavity at least one of the first pressure and the first chemical composition;
in a third method step, sealing the access opening by introducing energy or heat into an absorbing part of the substrate or the cap, with the aid of a laser;
wherein the access opening is completely filled by a material area of the substrate or the cap, which enters a liquid aggregate state in the third method step, the access opening being completely filled between a first plane, which extends parallel to a main extension plane of the substrate and is formed on a side, which faces away from the first cavity, of an area of the access opening formed perpendicularly to the main extension plane, and a second plane, which extends in parallel to the main extension plane of the substrate and is situated on a side, which faces toward the first cavity, of the area of the access opening formed perpendicularly to the main extension plane.

2. The method as recited in claim 1, wherein the energy or heat is introduced into the absorbing part of the substrate or the cap in such a way that the first plane extends along a surface, which faces away from the first cavity, of the substrate or the cap.

3. The method as recited in claim 1, wherein the energy or heat is introduced into the absorbing part of the substrate or the cap in such a way that the second plane extends essentially along a surface, which faces away from the first cavity, of the substrate or the cap.

4. The method as recited in claim 1, wherein the energy or heat is introduced into the absorbing part of the substrate or the cap in such a way that the material area has an extension from the first plane up to the second plane before the third method step.

5. A micromechanical component, comprising:
a substrate; and
a cap connected to the substrate, the cap, together with the substrate, enclosing a first cavity, a first pressure prevailing and a first gas mixture having a first chemical composition being enclosed in the first cavity, wherein the substrate or the cap includes a sealed access opening, the access opening being completely filled by a material area of the substrate or the cap, which enters a liquid aggregate state during sealing of the access opening, the access opening being completely filled between a first plane, which extends in parallel to a main extension plane of the substrate and is formed on a side, which faces away from the first cavity, of an area of the access opening formed perpendicularly to the main extension plane, and a second plane, which extends in parallel to the main extension plane of the substrate and is situated on a side, which faces toward the first cavity, of the area of the access opening formed perpendicularly to the main extension plane.

6. The micromechanical component as recited in claim 5, wherein the first plane extends along a surface, which faces away from the first cavity, of the substrate or the cap.

7. The micromechanical component as recited in claim 5, wherein the second plane extends along a surface, which faces toward the first cavity, of the substrate or the cap.

8. The micromechanical component as recited in claim 5, wherein the material area has an extension from the first plane up to the second plane before the sealing of the access opening.

9. The micromechanical component as recited in claim 5, wherein the cap, together with the substrate, encloses a second cavity, a second pressure prevailing and a second gas mixture having a second chemical composition being enclosed in the second cavity.

10. The micromechanical component as recited in claim 9, wherein the first pressure is lower than the second pressure, a first sensor unit for rotation rate measurement being situated in the first cavity and a second sensor unit for acceleration measurement being situated in the second cavity.
